(19) United States
(12) Patent Application Publication
(10) Pub. No.: US 2015/0345725 A1
(43) Pub. Date: Dec. 3, 2015

(54) TRANSFLECTIVE LIGHT ADJUSTING FILM AND THE METHOD FOR MANUFACTURING THEREOF

(71) Applicant: BenQ Materials Corporation, Taoyuan City (TW)

(72) Inventor: Fung-Hsu WU, Taoyuan City (TW)

(21) Appl. No.: 14/703,899

(22) Filed: May 5, 2015

(30) Foreign Application Priority Data
May 30, 2014 (TW) 103119087

(51) Int. Cl. F21S 11/00; C23C 14/22; C23C 16/44

(52) U.S. Cl. CPC F21S 11/007; C23C 16/44; C23C 14/22; Y02B 20/00

(57) ABSTRACT

The present invention is to provide a transflective light adjusting film, which includes a transparent substrate and a plurality of transparent grating-like stripe structures which are parallel to each other on the substrate. The transparent grating-like stripe structures have a plurality of top surfaces and a plurality of grooved surfaces, wherein a reflective layer is disposed on the grooved surfaces.

This application claims the priority benefit of Taiwanese application serial no. 103119087, filed on May 30, 2014, the full disclosure of which is incorporated herein by reference.

### BACKGROUND

1. Technical Field

The present invention is related to a light adjusting film, and more particularly is related to a transflective light adjusting film, which is used in the indoor lighting for providing energy saving performance and no rainbow defect observed in appearance.

2. Description of Related Art

Recently, with the raise of consciousness of energy saving, energy saving of building lighting has become a popular topic of research. In addition to utilize artificial lighting source to save energy, natural light is also promoted extensively.

For increasing the utilization rate of sunlight, light adjusting films with micro lens structures are usually used on the windows for concentrating sunlight toward the inside of buildings. However, in this way, the micro lens structures would cause rainbow-like defect easily so as to result in human eyes to feel uncomfortable and also decrease original light transmittance of the window. As a result, the conventional light adjusting film mentioned above could not provide the energy saving performance and good appearance at the same time.

For solving the problems mentioned above, the present invention provides a transflective light adjusting film and a method for manufacturing thereof. The transflective light adjusting film with the specific microstructures thereon provides light-transmissive regions and light-reflective regions at the same time. The specific micro structures of the transflective light adjusting film make no rainbow-like defect observed in the appearance. Moreover, the light-transmissive regions thereof can enhance the original transmittance of the window and the light-reflective regions thereof can reflect sunlight toward the ceiling in the room for enhancing the illumination of whole indoor areas so as to achieve energy saving performance.

### SUMMARY

According to aforementioned reasons, the present invention is to provide a novel transflective light adjusting film, which includes a transparent substrate and a plurality of transparent grating-like stripe structures which are parallel to each other on the substrate. The transparent grating-like stripe microstructures have a plurality of top surfaces and a plurality of grooved surfaces, wherein a reflective layer is disposed on the grooved surfaces.

According to an aspect of the present invention, the width of the transparent grating-like stripe microstructures of the transflective light adjusting film is in the range of 100 μm to 1000 μm.

According to an aspect of the present invention, the height of the transparent grating-like stripe microstructures of the transflective light adjusting film is in the range of 50 μm to 200 μm.

According to an aspect of the present invention, the pitch between two of the adjacent transparent grating-like stripe microstructures of the transflective light adjusting film is in the range of 50 μm to 1000 μm.

According to an aspect of the present invention, the reflective layer on the grooved surfaces of the transparent grating-like stripe microstructures is a metal coating layer.

The present is also to provide a method for manufacturing a transflective light adjusting film, which comprises the steps of: providing a transparent substrate; coating a curable resin on the transparent substrate; embossing the curable resin with a predetermined pattern to from a plurality of transparent grating-like stripe microstructures which are parallel to each other, wherein the transparent grating-like stripe microstructures have a plurality of top surfaces and a plurality of grooved surfaces; forming a protective layer on the top surfaces of the transparent grating-like stripe microstructures; forming a reflective layer on the protective layer and the grooved surfaces of the transparent grating-like stripe microstructures; and removing the protective layer and the reflective layer on the top surfaces of the transparent grating-like stripe microstructures.

According to an aspect of the present invention, the protective layer is formed by coating a protective agent on the top surfaces of the transparent grating-like stripe microstructures by a roller.

According to an aspect of the present invention, the protective agent is an oil-based coatings or a photoresist.

According to an aspect of the present invention, the reflective layer is formed on the protective layer and the grooved surfaces of the transparent grating-like stripe microstructures by chemical vapor deposition method or physical vapor deposition method.

According to an aspect of the present invention, the reflective layer on the protective layer and the grooved surfaces of the transparent grating-like stripe microstructures is a metal coating layer.

According to an aspect of the present invention, the protective layer and the reflective layer on the top surfaces are removed by a cleaning agent.

According to an aspect of the present invention, the cleaning agent is an oil-based solvent or an alkaline liquid.

According to an aspect of the present invention, the width of the transparent grating-like stripe microstructures is in the range of 100 μm to 1000 μm.

According to an aspect of the present invention, the height of the transparent grating-like stripe microstructures is in the range of 50 μm to 200 μm.

According to an aspect of the present invention, the pitch between two of the adjacent transparent grating-like stripe microstructures is in the range of 50 μm to 1000 μm.

### BRIEF DESCRIPTION OF THE DRAWINGS

FIG. 1 shows a cross-sectional schematic diagram of a transflective light adjusting film 100 of a preferred embodiment of the present invention.

FIG. 2 shows an optical path schematic diagram of sunlight passing through a transflective light adjusting film of the present invention.

FIG. 3 shows a schematic diagram of a transflective light adjusting film 300 of a preferred embodiment of the present invention.

FIGS. 4A to 4F show a schematic diagram for a manufacturing method of a transflective light adjusting film of a preferred embodiment of the present invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details.

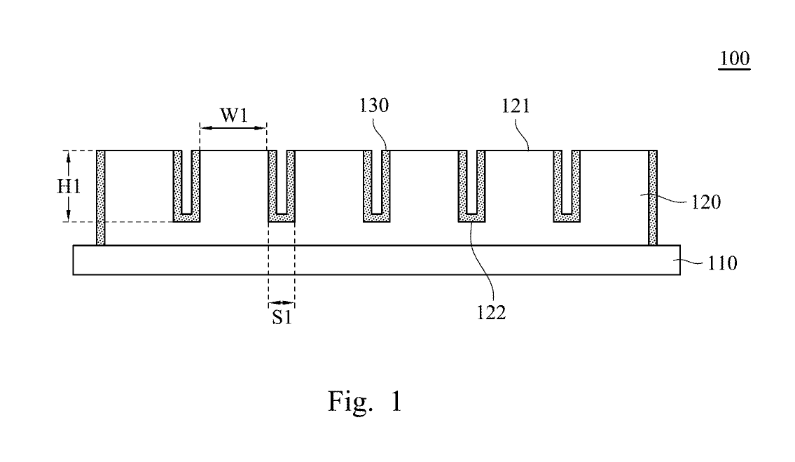

Referring to FIG. 1, a schematic diagram of a transflective light adjusting film 100 of a preferred embodiment of the present invention is shown. The transflective light adjusting film 100 includes a transparent substrate 110 and a plurality of transparent grating-like stripe structures 120 which are parallel to each other on the transparent substrate 110. The transparent grating-like stripe structures 120 have a plurality of top surfaces 121 and a plurality of the grooved surfaces 122. Moreover, a reflective layer 130 is disposed on the grooved surfaces 122 of transparent grating-like stripe structures 120.

In the transparent grating-like stripe structures 120, the top surfaces 121 are designed for light-transmissive regions where the incident light can pass through. On the other hand, the grooved surfaces 122 with the reflective layer 130 disposed thereon are designed for reflecting the incident light to the specific area in the room.

In an embodiment of the present invention, the width W1 of the transparent grating-like stripe microstructures 120 is in the range of 100 μm to 1000 μm, preferably in the range of 100 μm to 200 μm.

In another embodiment of the present invention, the height H1 of the transparent grating-like stripe microstructures 120 is in the range of 50 μm to 200 μm, preferably in the range of 50 μm to 100 μm.

In further another embodiment of the present invention, the pitch S1 between two of the adjacent transparent grating-like stripe microstructures 120 is in the range of 100 μm to 1000 μm, preferably in the range of 50 μm to 200 μm.

The width, height and the pitch of the transparent grating-like stripe microstructures is designed for the demands of users so that the ratio of the transmitted light and reflected light can be controlled arbitrarily. Accordingly, the design of grating-like stripe microstructures can be adjusted, but not limited thereto.

In a preferred embodiment of the present invention, the transparent substrate is selected from the group consisting of polyether, polyethylene terephthalate (PET), polycarbonate (PC), acrylate resin, polymethyl methacrylate (PMMA), polyurethane (PU) and a combination thereof.

In a preferred embodiment of the present invention, the transparent grating-like stripe microstructures are made of a curable resin, such as a thermo-curable resin or a UV curable resin.

In another preferred embodiment of the present invention, the reflective layer on the grooved surfaces of the transparent grating-like stripe microstructures is a metal coating layer.

In further another preferred embodiment of the present invention, the transparent grating-like stripe microstructures further includes a function layer disposed thereon, for example, such as a hard coating layer, an adhesive layer, an IR absorbing layer, a UV absorbing layer, an anti-fouling layer or a combination thereof.

In another preferred embodiment of the present invention, the side opposite to the transparent grating-like stripe microstructures of the transparent substrate further has an adhesive layer thereon so as to be laminated on the windows.

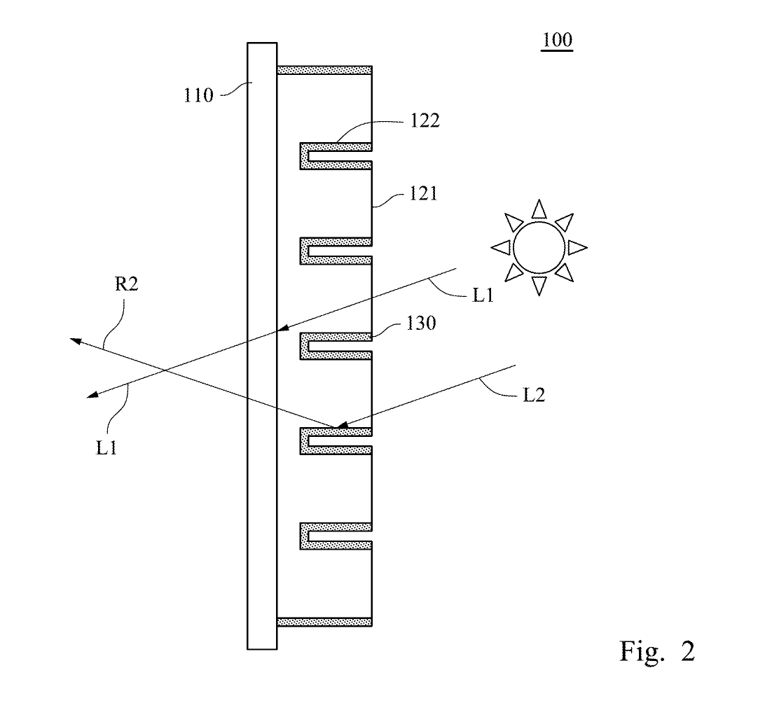

Referring to FIG. 2, an optical path of sunlight passing through a transflective light adjusting film 100 of a preferred embodiment of the present invention is shown. When the sunlight passes through the transflective light adjusting film 100, a part of sunlight L1 would pass through the top surfaces 121 of the transparent grating-like stripe microstructures. On the other hand, the other part of sunlight L2 would be reflected by the reflective layer 130 on the grooved surfaces 122 of the transparent grating-like stripe microstructures so as to form reflective light R2.

Due to the specific micro structures design, the transflective light adjusting of the present invention could provide the light-transmissive and light-reflective functions at the same time so as to maintain the original light transmittance of the window and reflect sunlight to the specific areas in the room for providing energy saving performance.

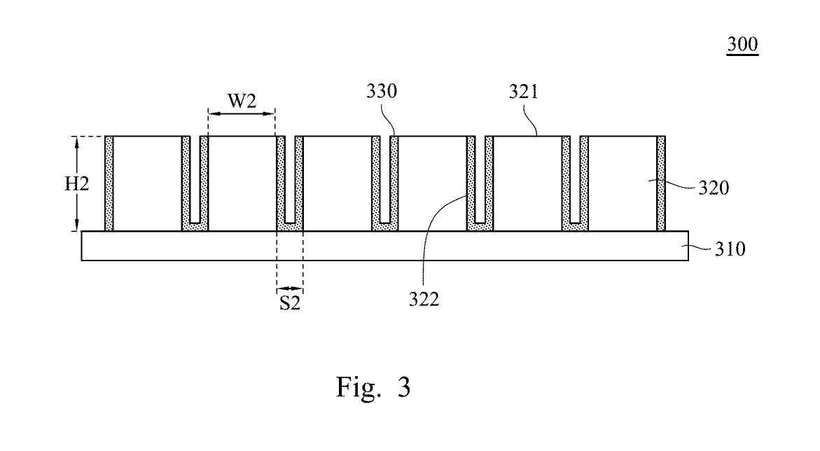

Referring to FIG. 3, a schematic diagram of a light adjusting film 300 of a preferred embodiment of the present invention is shown. The transflective light adjusting film 300 comprises a transparent substrate 310 and a plurality of transparent grating-like stripe structures 320 which are parallel to each other on the transparent substrate 310. The transparent grating-like stripe structures 320 have a plurality of top surfaces 321 and a plurality grooved surfaces 322. Moreover, a reflective layer 330 is disposed on the grooved surfaces 322 of transparent grating-like stripe structures 320.

The difference between the light adjusting film 300 and the light adjusting film 100 is the design of the transparent grating-like stripe structures. In an embodiment of the present invention, the width W2 of the transparent grating-like stripe microstructures 320 is in the range of 100 μm to 1000 μm, preferably in the range of 100 μm to 200 μm. In another embodiment of the present invention, the height H2 of the transparent grating-like stripe microstructures 320 is in the range of 50 μm to 200 μm, preferably in the range of 100 μm to 100 μm. In further another embodiment of the present invention, the pitch S2 two of the adjacent grating-like stripe microstructures 320 is in the range of 50 μm to 1000 μm, preferably in the range of 50 μm to 200 μm.

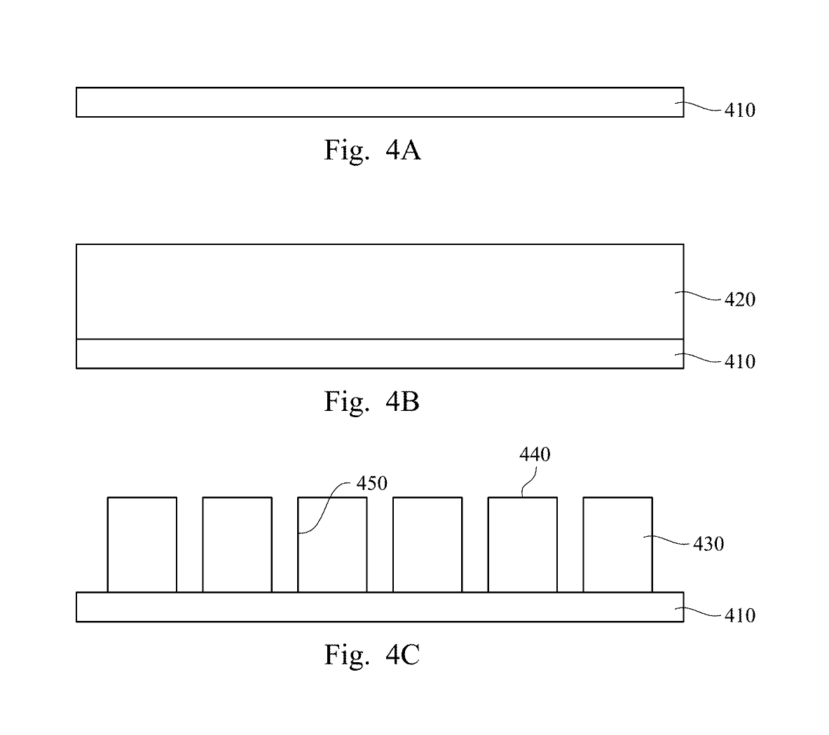

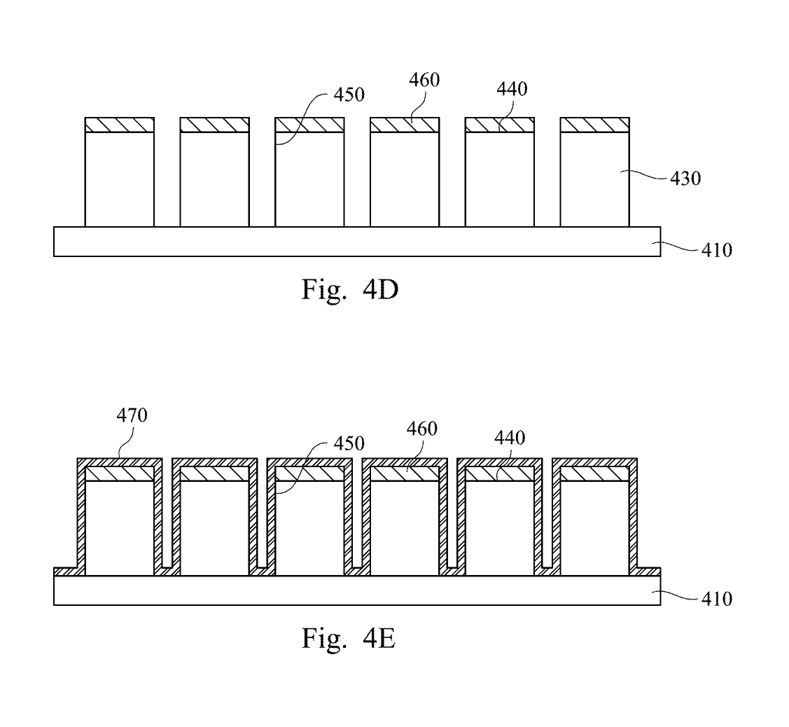

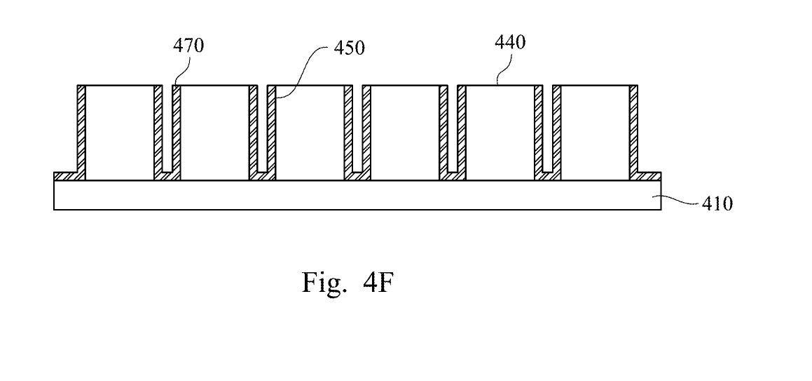

Referring to FIG. 4A to FIG. 4F, a schematic diagram for a manufacturing method of a transflective light adjusting film of a preferred embodiment of the present invention are shown.

First, the transparent substrate 410 is provided in the FIG. 4A. The transparent substrate 410 of the invention can be selected from a group consisting of a polyester, polyethylene terephthalate (PET), polycarbonate (PC), polyacrylate resin, polymethylmethacrylate (PMMA) and polyurethane.

Then, as indicated in FIG. 4B, a curable resin 420 is coated on the transparent substrate 410. The curable resin 420 is coated by a process known to an artisan skilled in the art, such as die coating or gravure coating. The curable resin 420 is selected from an UV curable resin or a thermo-curable resin, such as, for example, acrylic resin, polyurethane, polyester, silicone resin or epoxy resin.

In addition, the curable resin further includes an IR absorber, an UV absorber, an antifouling agent, an antibacterial agent or a combination thereof.

Then, as indicated in FIG. 4C. After the curable resin 420 is coated, the curable resin 420 is embossed with a predetermined pattern to form a plurality of transparent grating-like stripe structures 430 which are parallel to each other on the transparent substrate 410. The transparent grating-like stripe structures 430 have a plurality of top surfaces 440 and a plurality of grooved surfaces 450. The transparent grating-like stripe structures 430 is formed by embossing rollers or embossing device having a predetermined pattern on the surface thereof.

Next, as indicted in FIG. 4D, the protective layer 460 is formed by coating a protective agent on the top surfaces 440 of the transparent grating-like stripe microstructures by a roller. The protective agent is for example, such as an oil-based coatings or a photoresist.

Then, the reflective layer 470 is formed on the protective layer 460 and on the grooved surfaces 450 of the transparent grating-like stripe microstructures, as indicted in FIG. 4E. The reflective layer 470 is formed by chemical vapor deposition method or physical vapor deposition method. In a preferred embodiment of the present invention, the reflective layer is a metal coating layer.

In final, the protective layer 460 and the reflective layer 470 on the top surfaces of the transparent grating-like stripe microstructures are removed, as indicted in FIG. 4F. The protective layer 460 is removed by a cleaning agent. In a preferred embodiment of the present invention, the cleaning agent is for example, such as an oil-based solvent or an alkaline liquid. The cleaning agent would have higher solubility for the protective layer and lower solubility for the reflective layer. In this way, the cleaning agent can selectively decrease the adhesion force between the protective layer and the grating-like stripe microstructures so as to make the protective layer is easily removed from the transparent grating-like stripe microstructures. Meanwhile, the reflective layer disposed originally on the protective layer is also removed at the same time. But, the reflective layer on the grooved surfaces of the transparent grating-like stripe microstructures would still be maintained.

From the manufacturing method mentioned above, the transflective light adjusting film of the present invention can be obtained.

According to the user requirements, the functional layer can be coated on the surface of the grating-like stripe microstructures of the transflective light adjusting film, for example, such as a hard coating layer, an adhesive layer, an IR absorbing layer, an UV absorbing layer, an antifouling layer or the combination thereof. The adhesive layer can also be coated on the opposite side relative to the grating-like stripe microstructures of the transparent substrate so as to make the transflective light adjusting film to be laminated on the windows.

While the invention has been described by way of example(s) and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A transflective light adjusting film, comprising:
a transparent substrate;
a plurality of transparent grating-like stripe microstructures which are parallel to each other on the transparent substrate, wherein the transparent grating-like stripe microstructures have a plurality of top surfaces and a plurality of grooved surfaces, wherein a reflective layer which is disposed on the grooved surfaces.

2. The transflective light adjusting film according to claim 1, wherein the width of the grating-like stripe microstructures is in the range of 100 μm to 1000 μm.

3. The transflective light adjusting film according to claim 1, wherein the height of the grating-like stripe microstructures is in the range of 50 μm to 200 μm.

4. The transflective light adjusting film according to claim 1, wherein the pitch between two of the adjacent grating-like stripe microstructures is in the range of 50 μm to 1000 μm.

5. A method for manufacturing a transflective light adjusting film, comprising the steps of:
providing a transparent substrate;
coating a curable resin on the transparent substrate;
embossing the curable resin with a predetermined pattern to from a plurality of transparent grating-like stripe microstructures which are parallel to each other, wherein the transparent grating-like stripe microstructures have a plurality of top surfaces and a plurality of grooved surfaces;
forming a protective layer on the top surfaces of the transparent grating-like stripe microstructures;
forming a reflective layer on the protective layer and the grooved surfaces of the transparent grating-like stripe microstructures; and
removing the protective layer and the reflective layer on the top surfaces of the transparent grating-like stripe microstructures.

6. The method according to claim 5, wherein the protective layer is formed by coating a protective agent on the top surfaces of the transparent grating-like stripe microstructures by a roller.

7. The method according to claim 6, wherein the protective agent is an oil-based coatings or a photoresist.

8. The method according to claim 5, wherein the reflective layer is formed by chemical vapor deposition method or physical vapor deposition method.

9. The method according to claim 5, wherein the reflective layer is a metal coating layer.

10. The method according to claim 5, the protective layer and the reflective layer on the top surfaces are removed by a cleaning agent.

11. The method according to claim 10, wherein the cleaning agent is an oil-based solvent or an alkaline liquid.

12. The method according to claim 5, wherein the width of the transparent grating-like stripe microstructures is in the range of 100 μm to 1000 μm.

13. The method according to claim 5, wherein the height of the transparent grating-like stripe microstructures is in the range of 50 μm to 200 μm.

14. The method according to claim 5, wherein the pitch between two of the adjacent grating-like transparent stripe microstructures is in the range of 50 μm to 1000 μm.
